(19) United States
(12) Patent Application Publication
(10) Pub. No.: US 2024/0339412 A1
(43) Pub. Date: Oct. 10, 2024

(54) EMBEDDED INTERCONNECT BRIDGE WITH INDUCTOR FOR POWER DELIVERY

(71) Applicant: Intel Corporation, Santa Clara, CA (US)

(72) Inventors: Cary KULIASHA, Mesa, AZ (US); Brandon C. MARIN, Gilbert, AZ (US); Kristof DARMAWIKARTA, Chandler, AZ (US); Srinivas V. PIETAMBARAM, Chandler, AZ (US)

(21) Appl. No.: 18/130,584

(22) Filed: Apr. 4, 2023

(51) Int. Cl. H01L 23/538; H01L 23/64; H01L 25/065

(52) U.S. Cl. CPC H01L 23/5386; H01L 23/5384; H01L 23/645; H01L 25/0655; H01L 24/16; H01L 2224/16235; H01L 2924/1511

(57) ABSTRACT

Embodiments disclosed herein include an interconnect bridge. In an embodiment, the interconnect bridge comprises a substrate, and a first trace on the substrate. In an embodiment, a first layer is on the first trace, where the first layer comprises a magnetic material. In an embodiment, a second layer is over the substrate, where the second layer comprises an insulating material. In an embodiment, a second trace is embedded in the second layer.

### TECHNICAL FIELD

Embodiments of the present disclosure relate to electronic systems, and more particularly to electronic packages with embedded interconnect bridges that include integrated inductors for power delivery applications.

### BACKGROUND

Passive electrical components (e.g., capacitors and inductors) are important components of substrate packaging that enable efficient power delivery to voltage regulators located on the overlying dies. Logic-side power delivery currently requires passive components attached to the land/die side of the substrate surface (e.g., multi-layer ceramic capacitors, magnetic inductor arrays, etc.) or embedded within the substrate core. These passive components help to maintain constant voltage and reduce noise and impedance to voltage regulator rails.

Land/die side capacitors and inductors have significant performance limitations due to the routing losses that accumulate over the long-distance power-delivery signals must travel between the components and the die-side voltage regulator rails. Embedding these passive components into the substrate core to lower the routing length is one possible solution path. However, current processes are primarily limited to ultra-thin-core products due to significant processing difficulties with thicker core products. Coaxial inductor solutions embedded in the core is another solution path, but is limited due to a tradeoff between inductor performance and manufacturability. Thus, limiting their effective performance envelope.

### BRIEF DESCRIPTION OF THE DRAWINGS

FIG. 1A is a cross-sectional illustration of a bridge die with an integrated inductor, in accordance with an embodiment.

FIG. 1B is a plan view illustration of the bridge die in FIG. 1A that illustrates a bump layout, in accordance with an embodiment.

FIG. 1C is a plan view illustration of a magnetic layer with a spiral inductor trace, in accordance with an embodiment.

FIG. 1D is a plan view illustration of a magnetic layer with a serpentine inductor trace, in accordance with an embodiment.

FIG. 2A is a cross-sectional illustration of a bridge die with a multi-layer integrated inductor, in accordance with an embodiment.

FIG. 2B is an illustration of a first layer and a second layer of the multi-layer inductor, in accordance with an embodiment.

FIG. 3A is a cross-sectional illustration of a bridge die with an integrated inductor on the bottom of the die, in accordance with an embodiment.

FIG. 3B is a cross-sectional illustration of a bridge die with an integrated inductor on the bottom of the die with backside vias, in accordance with an embodiment.

FIG. 4A is a cross-sectional illustration of a bridge die with an integrated inductor with input and output pads at an edge of the bridge die, in accordance with an embodiment.

FIG. 4B is a plan view illustration of the bridge die in FIG. 4A that illustrates the bump pattern, in accordance with an embodiment.

FIG. 5A is a cross-sectional illustration of a die, in accordance with an embodiment.

FIG. 5B is a cross-sectional illustration of the die after inductor traces and vias are formed, in accordance with an embodiment.

FIG. 5C is a cross-sectional illustration of the die after a magnetic layer is applied over the inductor traces, in accordance with an embodiment.

FIG. 5D is a cross-sectional illustration of the die after the vias and magnetic layer are planarized, in accordance with an embodiment.

FIG. 5E is a cross-sectional illustration of the die after a first buildup layer is provided over the magnetic layer, in accordance with an embodiment.

FIG. 5F is a cross-sectional illustration of the die after additional buildup layers and electrical routing are provided over the die, in accordance with an embodiment.

FIG. 6 is a cross-sectional illustration of a bridge die that includes an integrated inductor structure and an integrated capacitor structure, in accordance with an embodiment.

FIG. 7A is a cross-sectional illustration of an electronic package with an embedded bridge with an integrated inductor, in accordance with an embodiment.

FIG. 7B is a cross-sectional illustration of an electronic package with an embedded bridge with an integrated inductor, in accordance with an additional embodiment.

FIG. 8A is a cross-sectional illustration of an electronic system that includes a bridge with an integrated inductor, in accordance with an embodiment.

FIG. 8B is a cross-sectional illustration of an electronic system that includes a bridge with an integrated inductor, in accordance with an additional embodiment.

FIG. 9 is a schematic of a computing device built in accordance with an embodiment.

### EMBODIMENTS OF THE PRESENT DISCLOSURE

Described herein are electronic systems, and more particularly, electronic packages with embedded interconnect bridges that include integrated inductors for power delivery applications, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing architectures for the integration of passive components are limited. For example, discrete passive components lead to high routing losses due to their distance from the voltage regulator. Integrated passives, such as coaxial inductor structures embedded in the core, are also limited in design due to material and manufacturability concerns.

Accordingly, embodiments disclosed herein provide integrated passive devices (e.g., inductors and capacitors) directly on the embedded bridge. Having power delivery components within the embedded bridge offers an optimized routing distance to the die-side voltage regulator (VR) rails. Further, high capacitance density and inductance density can be achieved using silicon processing technologies compatible with the bridge die. Additionally, utilizing existing embedding process flows for embedded bridge architectures will make the package substrate processing relatively straight forward since integrated passives may be omitted from the package substrate. Integration of passives into the embedded bridge also utilizes existing silicon real estate within the bridge body that currently has no functional purpose.

More particularly, embedded bridge architectures disclosed herein include an inductor layer. The inductor layer may be provided over the bridge die or under the bridge die. The inductor layer comprises conductive traces that are formed in an inductive pattern (e.g., coil pattern or serpentine pattern). Vias to the conductive traces may then be formed to the front side or backside of the bridge. The inductor layer may include a magnetic material over the inductive pattern in order to further increase the inductance of the inductor layer. In some embodiments, two or more inductor layers may be provided over each other as well. While inductor architectures are described in detail herein, it is to be appreciated that integrated capacitor structures may be used in conjunction with the integrated inductor architectures.

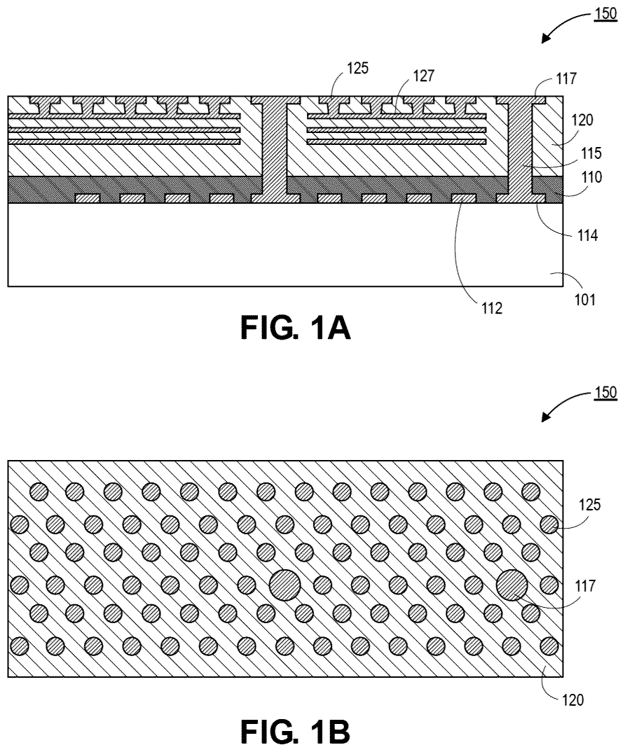

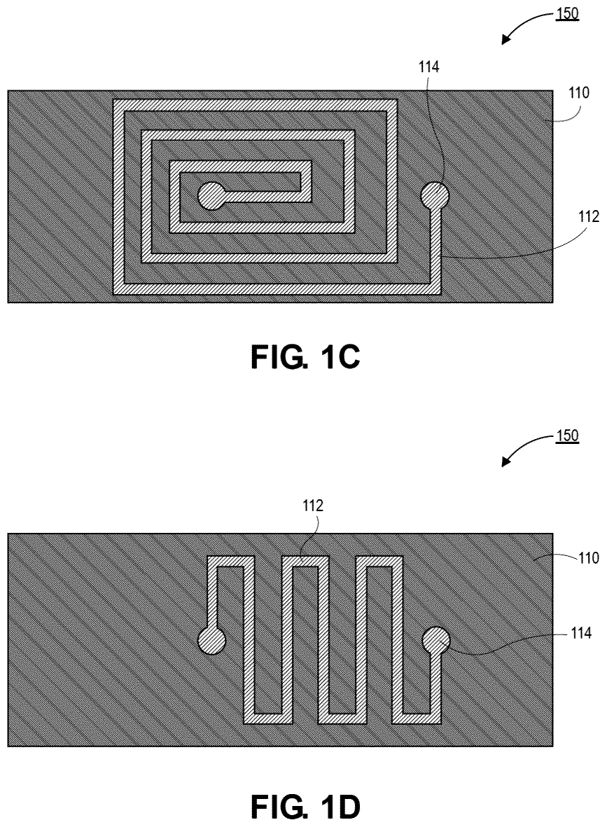

Referring now to FIG. 1A, a cross-sectional illustration of a bridge 150 is shown, in accordance with an embodiment. In an embodiment, the bridge 150 may be a bridge 150 that is embedded in a package substrate (not shown). The bridge 150 may be used to electrically couple together a pair of dies. Additionally, embodiments include a bridge 150 with an integrated inductor in order to provide passive components that are coupled to VRs of the overlying dies.

In an embodiment, the bridge 150 may comprise a substrate 101. The substrate 101 may be a silicon substrate. Though, the substrate 101 may be other materials, such as glass or the like. In some embodiments, the substrate 101 may be a dummy substrate. That is, there may not be any active circuitry (e.g., transistors, etc.) on the substrate 101. The substrate 101 may serve as a dimensionally stable base onto which interconnects and passives are formed.

In an embodiment, an inductor layer may be provided over a top surface of the substrate 101. The inductor layer may comprise electrically conductive traces 112. The traces 112 may terminate at pads 114. In an embodiment, the traces 112 may have a pattern suitable for providing high inductances. For example, the traces 112 may be coils or a serpentine pattern. In an embodiment, the inductor layer may further comprise a magnetic material 110 over the traces 112. The magnetic material 110 may be any suitable magnetic material that is compatible with bridge 150 fabrication. For example, the magnetic material 110 may comprise cobalt and iron, any other ferrite material, any high permeability material, or the like.

In an embodiment, routing layers 120 may be provided above the inductor layer. The routing layers 120 may include electrically conductive traces 127 that couple together pads 125. The traces 127 may be provided in one or more routing layers 120. The traces 127 may be high density traces. For example, a line/spacing (L/S) dimension of the traces 127 may be approximately 5 μm/5 μm or less, or approximately 2 μm/2 μm or less. As used herein, “approximately” may refer to a range of values that are within ten percent of the stated value. For example, approximately 5 μm may refer to a range between 4.5 μm and 5.5 μm.

In an embodiment, the inductor layer may be coupled to the top surface of the bridge 150 by vias 115. The vias 115 may pass through the routing layers 120 and the magnetic material 110 in order to contact pads 114 in the inductor layer. Pads 117 may be provided over the vias 115 on the top side of the bridge 150. The pads 117 may be positioned so that they are proximate to VR devices in the overlying dies (not shown). As such, the distance between the inductor and the VR is minimized.

Referring now to FIG. 1B, a plan view illustration of the top surface of a bridge 150 is shown, in accordance with an embodiment. As shown, the top routing layer 120 may include a plurality of pads 125. The pads 125 may be for signals that are passed between an overlying pair of dies. The pads 125 may have any suitable layout. In an embodiment, pads 117 may also be provided on the top routing layer 120. The pads 117 may be provided in the middle of the bridge 150 and/or proximate to an edge of the bridge 150. Generally, the pads 117 may be provided at any location across the bridge 150. The pads 117 may be larger than the pads 125 since they are used for power delivery applications. In the illustrated embodiment, two pads 117 are shown. The two pads 117 may be used as an input and an output of a single inductor. While a single inductor structure is shown in FIG. 1B, it is to be appreciated that any number of inductors may be used in the bridge 150.

Referring now to FIG. 1C, a plan view illustration of the inductor layer of the bridge 150 is shown, in accordance with an embodiment. As noted above, the inductor layer includes a trace 112 that is formed in a magnetic material 110. The trace 112 may have a pattern that is useful for generating an inductance. For example, in FIG. 1C the trace 112 has a coil pattern. The first end and the second end of the trace 112 may terminate at pads 114. It is to be appreciated that the coil may have any number of loops or turns. Additionally, since the trace 112 is formed on the underlying substrate, the trace may have fine dimensions. For example, a width of the traces 112 may be approximately 5 μm or less or approximately 2 μm or less. As such, a high inductance density can be provided in the bridge 150.

Referring now to FIG. 1D, a plan view illustration of the inductor layer of a bridge 150 is shown, in accordance with an additional embodiment. As shown, the trace 112 has a serpentine pattern. The dimensions of the serpentine pattern may be any suitable dimensions and there may be any number of turns in order to provide a desired inductance. While examples of a coil pattern and a serpentine pattern are shown in FIGS. 1C and 1D, it is to be appreciated that the traces 112 may have any shape or pattern that is capable of generating an inductance.

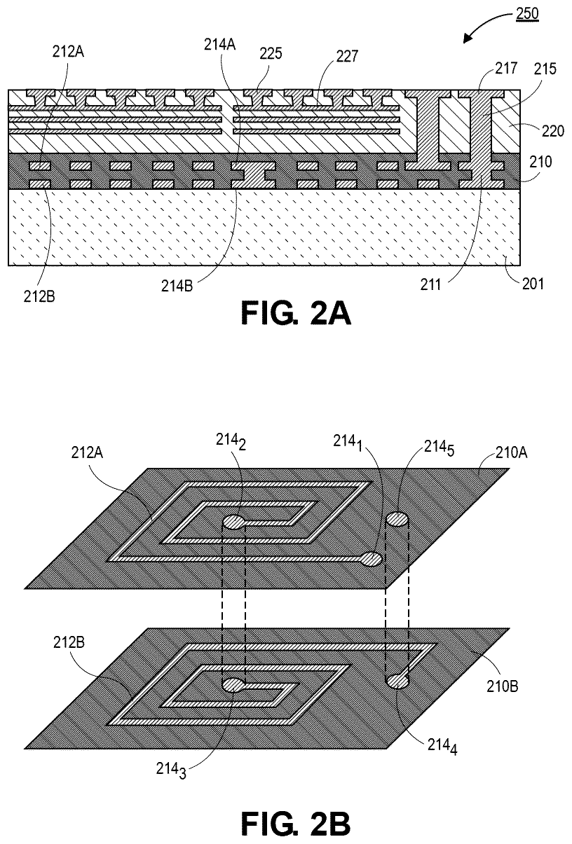

Referring now to FIG. 2A, a cross-sectional illustration of a bridge 250 is shown, in accordance with an additional embodiment. As shown, the bridge 250 may comprise a substrate 201, such as a silicon die or the like. In an embodiment, an inductor layer is provided over the substrate 201. Additionally, routing layers 220 are provided over the inductor layer. The routing layers 220 may comprise traces 227 and pads 225.

In an embodiment, the inductor layer may include a dual layer inductor. For example, a first layer including first traces 212A may be provided over a second layer including second traces 212B. A pad 214A in the first layer may be electrically coupled to a pad 214B in the second layer by a via 211. The first traces 212A may form a first inductor, and the second traces 212B may form a second inductor. In an embodiment, the first inductor is connected to the second inductor in series. An input and an output to the connected inductors may be provided through vias 215 and pads 217.

In an embodiment, a magnetic material 210 is provided over and around the first traces 212A and the second traces 212B. The magnetic material 210 may be any suitable magnetic material, such as a ferrite, or any high permeability material. For example, the magnetic material 210 may comprise cobalt and iron in some embodiments. The magnetic material 210 may be applied as multiple layers. For example, a first layer of the magnetic material 210 may be applied around the second traces 212B, and a second layer of the magnetic material 210 may be applied around the first traces 212A. As such, there may be a seam within the magnetic material 210 in some embodiments.

Referring now to FIG. 2B, a perspective exploded view of the inductor layer is shown, in accordance with an embodiment. As shown, a first magnetic material 210A is provided over a second magnetic material 210B. The first traces 212A may form a first coil pattern in the first magnetic material 210A, and the second traces 212B may form a second coil pattern in the second magnetic material 210B. In an embodiment, the first coil pattern may be a chiral image of the second coil pattern. Additionally, the direction of current flow may be opposite in the different layers. For example, current goes from the outer pad 2141 to the inner pad 2142 in the first layer, and current goes from the inner pad 2143 to the outer pad 2144 in the second layer. As shown in FIG. 2B, the dashed lines indicate locations of vias between the layers. For example, pad 2142 is coupled to pad 2143 by a via, and pad 2144 is coupled to pad 2145 by a via.

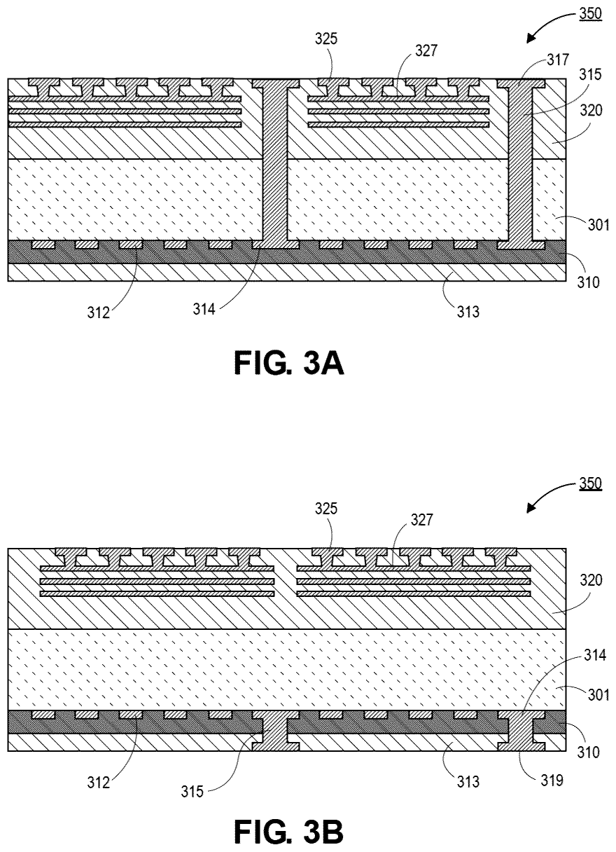

Referring now to FIG. 3A, a cross-sectional illustration of a bridge 350 is shown, in accordance with an additional embodiment. In an embodiment, the bridge 350 may comprise a substrate 301. The substrate 301 may include a silicon substrate or the like. In an embodiment, routing layers 320 are provided over the top surface of the substrate 301. The routing layers 320 may comprise electrically conductive traces 327 that are used to communicatively couple multiple dies together. The conductive traces 327 may be provided in one or more of the routing layers 320. Additionally, the traces 327 may be coupled to pads 325 at the top surface of the bridge 350.

In an embodiment, an inductor layer is provided on a backside of the substrate 301. That is, the inductor layer is provided on a surface of the substrate 301 opposite from the routing layers 320. The inductor layer may include traces 312. The traces may include any suitable pattern for generating inductance. For example, the traces 312 may have a coil pattern, a serpentine pattern, or the like. In an embodiment, the traces 312 may be surrounded by a magnetic material 310. The magnetic material 310 may be a ferrite, such as a material comprising cobalt and iron, or any high permeability material. In an embodiment an insulating layer 313 may be provided over the magnetic material 310.

Ends of the traces 312 may terminate at pads 314. In an embodiment, the pads 314 may be coupled to pads 317 on the front side of the bridge 350 by vias 315. More particularly, the vias 315 may pass through the substrate 301 and the routing layers 320. The portion of the via 315 that passes through the substrate 301 may be considered a through silicon via (TSV) in some embodiments.

Referring now to FIG. 3B, a cross-sectional illustration of a bridge 350 is shown, in accordance with an additional embodiment. In an embodiment, the bridge 350 may comprise a substrate 301. The substrate 301 may include a silicon substrate or the like. In an embodiment, routing layers 320 are provided over the top surface of the substrate 301. The routing layers 320 may comprise electrically conductive traces 327 that are used to communicatively couple multiple dies together. The conductive traces 327 may be provided in one or more of the routing layers 320. Additionally, the traces 327 may be coupled to pads 325 at the top surface of the bridge 350.

In an embodiment, an inductor layer is provided on a backside of the substrate 301. That is, the inductor layer is provided on a surface of the substrate 301 opposite from the routing layers 320. The inductor layer may include traces 312. The traces may include any suitable pattern for generating inductance. For example, the traces 312 may have a coil pattern, a serpentine pattern, or the like. In an embodiment, the traces 312 may be surrounded by a magnetic material 310. The magnetic material 310 may be a ferrite, such as a material comprising cobalt and iron, or any high permeability material. In an embodiment an insulating layer 313 may be provided over the magnetic material 310.

Ends of the traces 312 may terminate at pads 314. In an embodiment, the pads 314 may be coupled to pads 319 on the backside of the bridge 350 by vias 315. More particularly, the vias 315 may pass through the magnetic material 310 and the insulating layer 313. As such, embodiments may include bridge 350 architectures with pads on both the top and bottom of the bridge 350. That is, pads 325 for die-to-die connections may be provided on the top surface of the bridge 350, and pads 319 for power delivery passives may be provided on the bottom surface of the bridge 350.

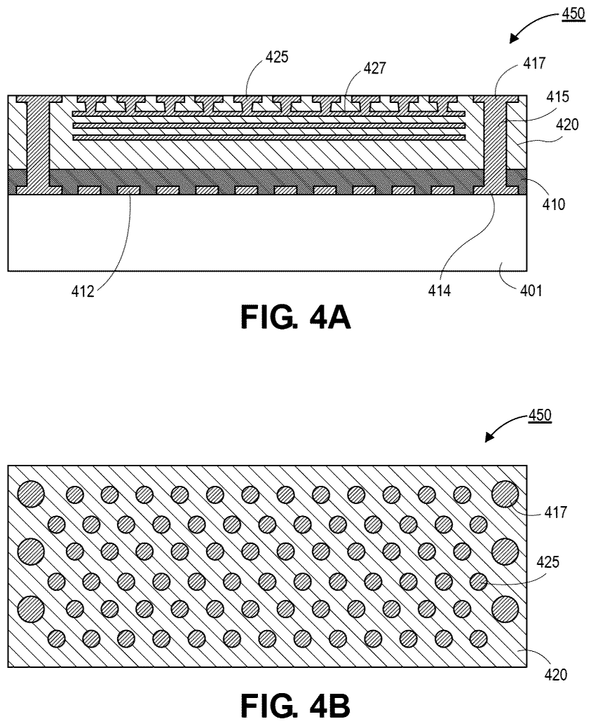

Referring now to FIG. 4A, a cross-sectional illustration of a bridge 450 is shown, in accordance with an embodiment. In an embodiment, the bridge 450 may comprise a substrate 401. The substrate 401 may include a silicon substrate or the like. In an embodiment, an inductor layer is provided over a top surface of the substrate 401. The inductor layer may comprise traces 412 that are directly on the substrate 401. The traces 412 may include any suitable pattern for generating inductance. For example, the traces 412 may be in a coil pattern, a serpentine pattern, or the like. The traces 412 may terminate at pads 414. In an embodiment, a magnetic material 410 is provided over and around the traces 412. The magnetic material 410 may comprise a ferrite, such as a ferrite comprise cobalt and iron. The magnetic material 410 may comprise any high permeability material.

In an embodiment, routing layers 420 are provided over the top surface of the magnetic material 410. The routing layers 420 may comprise electrically conductive traces 427 that are used to communicatively couple multiple dies together. The conductive traces 427 may be provided in one or more of the routing layers 420. Additionally, the traces 427 may be coupled to pads 425 at the top surface of the bridge 450.

In an embodiment, the pads 414 in the inductor layer may be coupled to pads 417 on a top surface of the bridge 450 by vias 415. The vias 415 may pass through the magnetic material 410 and the routing layers 420. In an embodiment, the vias 415 may be provided along edges of the bridge 450.

Referring now to FIG. 4B, a plan view illustration of the bridge 450 in FIG. 4A is shown, in accordance with an embodiment. As shown, pads 425 are distributed across a surface of the routing layer 420. In an embodiment, pads 417 coupled to the inductor layer are provided along the edges of the bridge 420. Additionally, it is to be appreciated that multiple pairs of pads are provided. More particularly, embodiments may include multiple inductors within the bridge 450, with each inductor having an input pad 417 and an output pad 417. In an embodiment, the pads 417 may be larger in diameter than the pads 425. This is because the pads 417 are for power delivery applications, and pads 425 are for signal propagation.

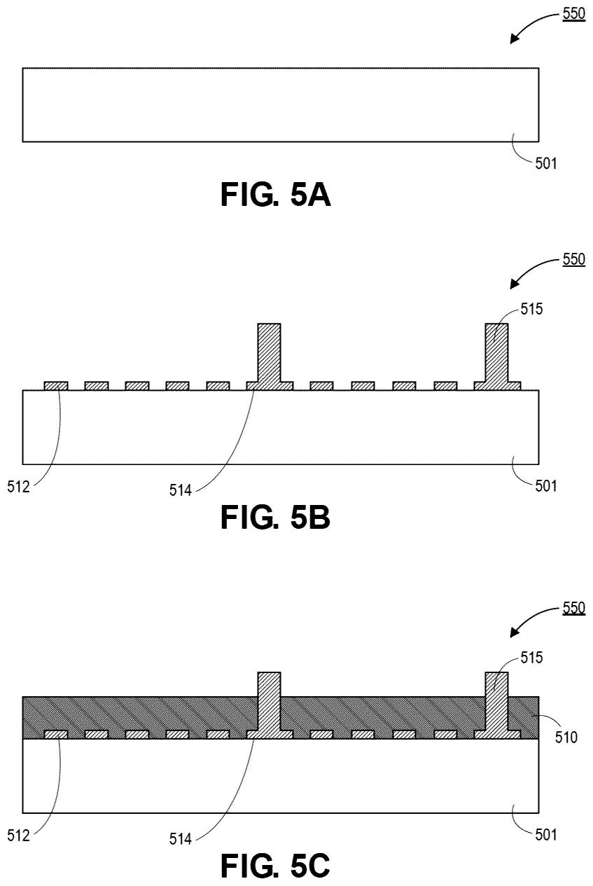

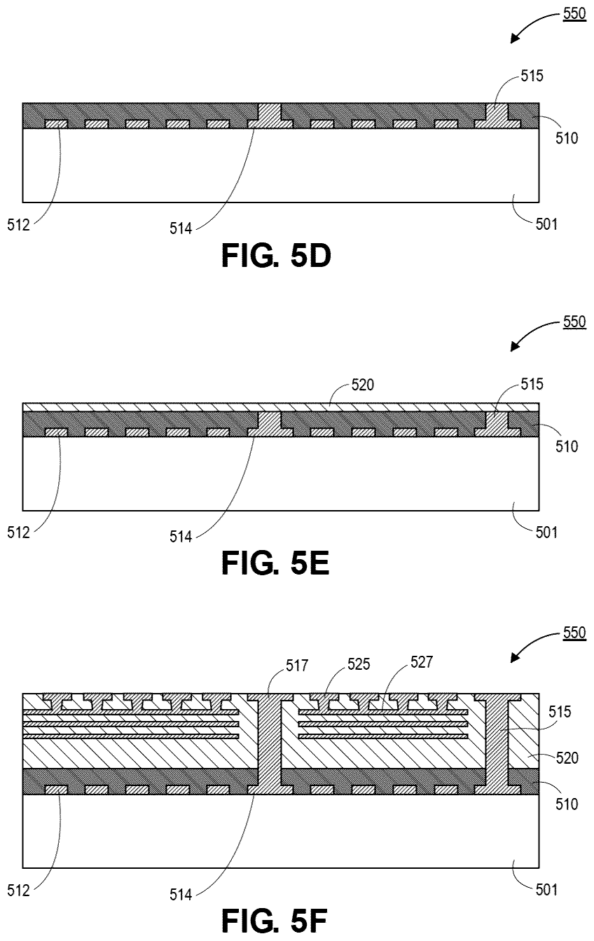

Referring now to FIGS. 5A-5F, a series of cross-sectional illustrations depicting a process for forming a bridge 550 with an integrated inductor layer is shown, in accordance with an embodiment. The bridge 550 in FIGS. 5A-5F may be similar to the bridge 150 in FIG. 1A. Though, it is to be appreciated that standard processing operations may be used in combination in order to fabricate bridges similar to any of the architectures described in greater detail herein.

Referring now to FIG. 5A, a cross-sectional illustration of a bridge 550 at a stage of manufacture is shown, in accordance with an embodiment. In an embodiment, the bridge 550 may comprise a substrate 501. The substrate 501 may be a silicon substrate, or any other suitable material for use in a bridge 550 (e.g., glass, etc.). The substrate 501 may be a dummy substrate. That is, there may not be any active circuitry (e.g., transistors, etc.) fabricated into the substrate 501. Though, embodiments may include active circuitry in some embodiments.

Referring now to FIG. 5B, a cross-sectional illustration of the bridge 550 after conductive routing for an inductor layer is formed is shown, in accordance with an embodiment. In an embodiment, the conductive routing may include traces 512 and pads 514. The ends of the traces 512 may terminate at the pads 514. The traces 512 may have any suitable pattern for generating an inductance. For example, the traces 512 may have a coil pattern, a serpentine pattern, or the like. In an embodiment, vias 515 may be provided over the pads 514. The vias 515 may be copper pillars.

Referring now to FIG. 5C, a cross-sectional illustration of the bridge 550 after a magnetic layer 510 is applied over the substrate 501 is shown, in accordance with an embodiment. In an embodiment, the magnetic layer 510 may be provided over and around the traces 512 and pads 514. The magnetic layer 510 may have a top surface that is below the top surface of the vias 515. In an embodiment, the magnetic layer 510 may comprise a ferrite, such as a ferrite comprising cobalt and iron. The magnetic layer 510 may comprise any high permeability material. In an embodiment, the magnetic layer 510 may be applied with any suitable process. For example, chemical vapor deposition (CVD) may be used to deposit the magnetic layer 510 over the traces 512.

Referring now to FIG. 5D, a cross-sectional illustration of the bridge 550 after a polishing process is shown, in accordance with an embodiment. In an embodiment, a polishing process may be used to recess the vias 515 so that a top surface of the vias 515 is substantially coplanar with a top surface of the magnetic layer 510. The polishing process may also recess a portion of the magnetic layer 510 in some embodiments. In an embodiment, the polishing process may be a chemical mechanical polishing (CMP) process.

Referring now to FIG. 5E, a cross-sectional illustration of the bridge 550 after a routing layer 520 is provided over the magnetic layer 510 is shown, in accordance with an embodiment. In an embodiment, the routing layer 520 may comprise an electrically insulating material. For example, the routing layer 520 may comprise silicon and oxygen (e.g., SiO₂) or the like. The routing layer 520 may be applied with any suitable deposition process.

Referring now to FIG. 5F, a cross-sectional illustration of the bridge 550 after additional routing layers 520 are formed is shown, in accordance with an embodiment. As shown, the routing layers 520 may include traces 527 for routing between pads 525. Portions of the vias 515 may also be fabricated through the routing layers 520. The vias 515 may terminate at pads 517.

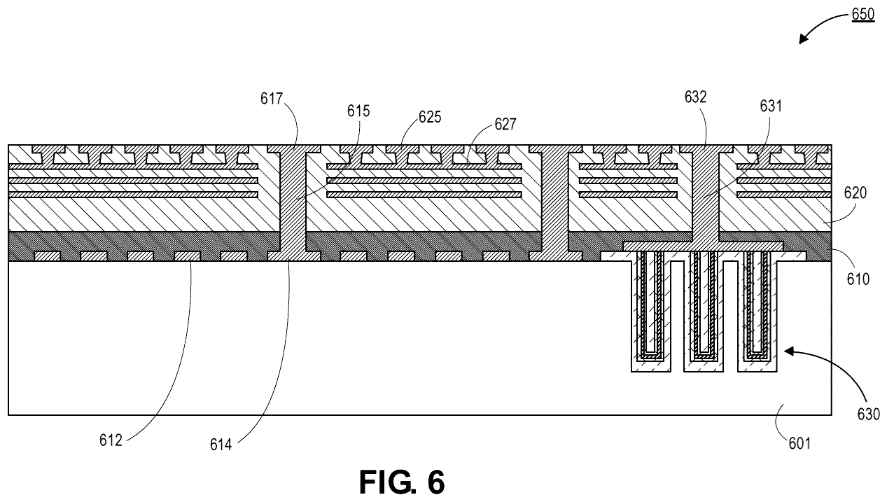

Referring now to FIG. 6, a cross-sectional illustration of a bridge 650 is shown, in accordance with yet another embodiment. In an embodiment, the bridge 650 may comprise a substrate 601, such as a silicon substrate or the like. In an embodiment, the bridge 650 may include an integrated inductor structure and an integrated capacitor structure. For example, inductor traces 612 and pads 614 may be embedded in a magnetic layer 610. Additionally, one or more capacitor structures 630 may be formed in trenches into the substrate 601. The inductor traces 612 may be coupled to the top surface of the bridge 650 by pads 614 and vias 615 that end at pads 617. The capacitor structures 630 may be coupled to the top surface of the bridge 650 by vias 631 that end at pads 632. Additionally, conductive routing 627 and pads 625 may be provided in routing layers 620 above the inductor structure and the capacitor structures 630.

In FIG. 6, the inductor structure is similar to the inductor structure shown in the bridge 150 in FIG. 1A. However, it is to be appreciated that any inductor architecture disclosed herein may be used in conjunction with integrated capacitor structures 630. For example, the inductor structure and the capacitor structures 630 may be provided on opposite surfaces of the substrate 601, both of the inductor structure and the capacitor structures 630 may be formed on the backside of the substrate 601, or any other suitable combination.

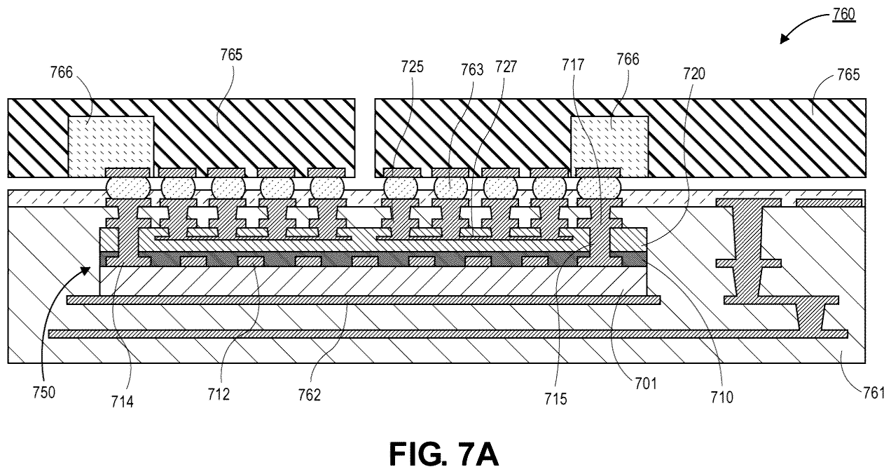

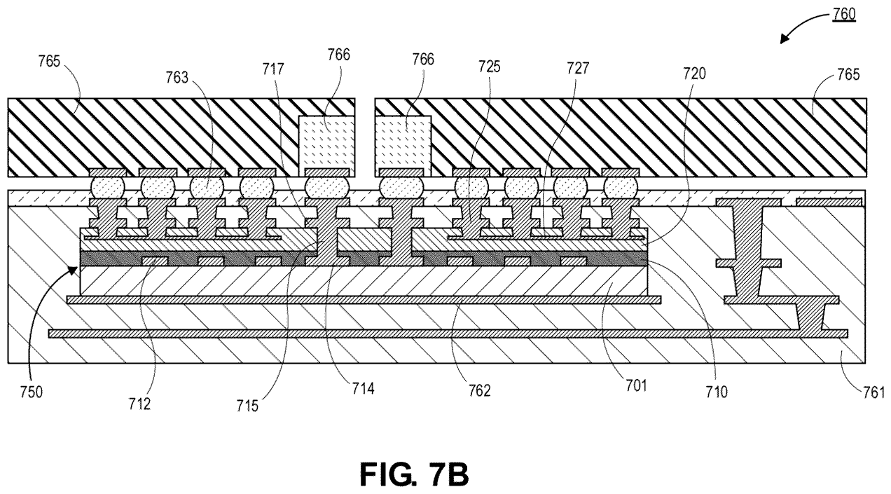

Referring now to FIG. 7A, a cross-sectional illustration of an electronic package 760 is shown, in accordance with an embodiment. In an embodiment, the electronic package 760 comprises a package substrate 761. A bridge 750 may be embedded in the package substrate 761. For example, the bridge 750 may be provided over an etchstop layer 762 within the package substrate 761. In an embodiment, the bridge 750 may communicatively couple a first die 765 to a second die 765. For example, pads 725 and traces 727 in the routing layers 720 may provide the coupling between dies 765. The dies 765 may be coupled to the bridge 750 through interconnects 763, such as solder balls or any other suitable first level interconnect (FLI) architecture.

In an embodiment, the bridge 750 may be similar to any of the bridge architectures described herein. For example, the bridge 750 may comprise a substrate 701, such as a silicon substrate or the like. A magnetic layer 710 may be provided over the substrate 701. Inductor traces 712 may be embedded within the magnetic layer 710. The inductor traces 712 may be coupled to pads 717 on the top of the bridge 750 by pads 714 and vias 715. The top pads 717 may be coupled to VR regions 766 of the dies 765.

Referring now to FIG. 7B, a cross-sectional illustration of an electronic package 760 is shown, in accordance with an additional embodiment. The electronic package 760 in FIG. 7B may be substantially similar to the electronic package 760 in FIG. 7A, with the exception of the location of the VR regions 766. Instead of being provided over the edge of the bridge 750, the VR regions 766 are provided at a center of the bridge 750 (i.e., towards the edges of the dies 765). That is, the vias 715 and pads 717 may be provided towards a center of the bridge 750. Additionally, the pads 725 for routing 727 between dies 765 may be towards the outer edges of the bridge 750.

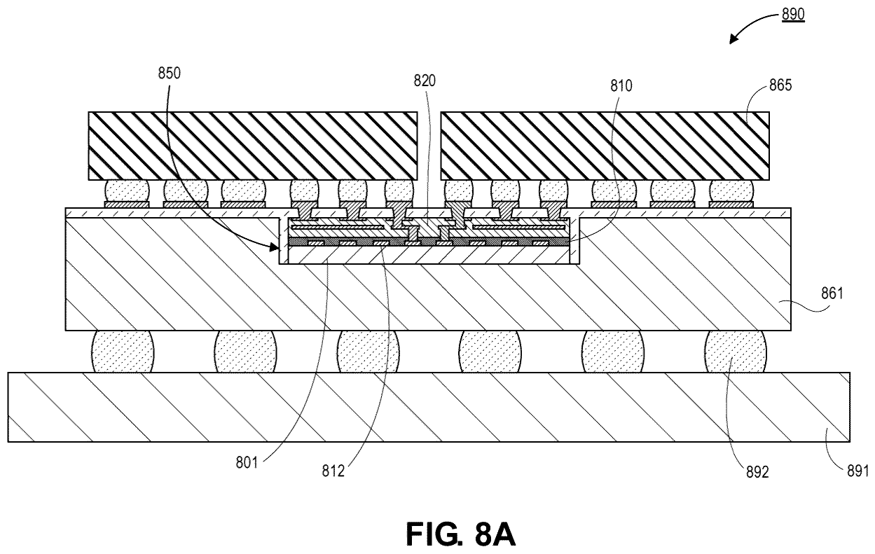

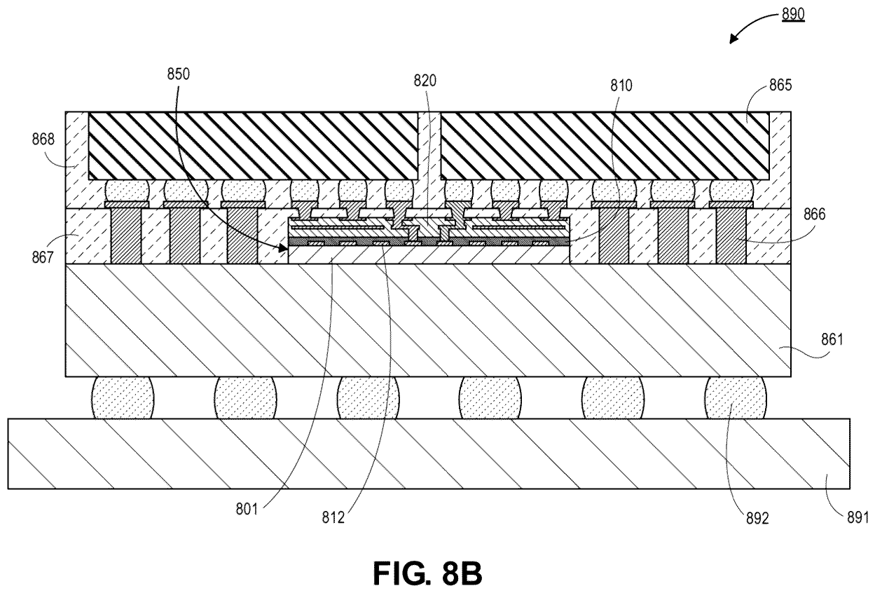

Referring now to FIG. 8A, a cross-sectional illustration of an electronic system 890 is shown, in accordance with an embodiment. In an embodiment, the electronic system 890 may comprise a board 891, such as a printed circuit board (PCB). In an embodiment, a package substrate 861 may be coupled to the board 891 through interconnects 892. The interconnects 892 may be solder balls, sockets, or any other suitable interconnect architecture.

In an embodiment two or more dies 865 may be provided over the package substrate 861. The dies 865 may be compute dies. For example, the dies 865 may include a central processing unit (CPU), a graphics processing unit (GPU), an XPU, a system on a chip (SoC), a communications die, a memory die, or the like. In an embodiment, the dies 865 may be communicatively coupled together by a bridge 850 that is embedded in the package substrate 861.

In an embodiment, the bridge 850 may be similar to any of the bridge architectures described herein. In a particular embodiment, the bridge 850 comprises a substrate 801, such as a silicon substrate. In an embodiment, a magnetic layer 810 embeds inductor traces 812. Routing layers 820 may be provided above the magnetic layer 810. In an embodiment, the inductor traces 812 are coupled to VR regions in the overlying dies 865.

Referring now to FIG. 8B, a cross-sectional illustration of an electronic system 890 is shown, in accordance with an additional embodiment. In an embodiment, the electronic system 890 may be similar to the electronic system 890 in FIG. 8A, with the exception of the bridge 850 being provided above the package substrate 861. In order to account for the additional stand-off height occupied by the bridge 850, pillars 866 (e.g., copper pillars 866) may be provided to couple the dies 865 to the package substrate 861. In an embodiment, the bridge 850 and the pillars 866 may be embedded in a first mold layer 867, and the dies 865 may be embedded in a second mold layer 868. Though, a single mold layer may also be used to embed all of the components above the package substrate 861 in some embodiments.

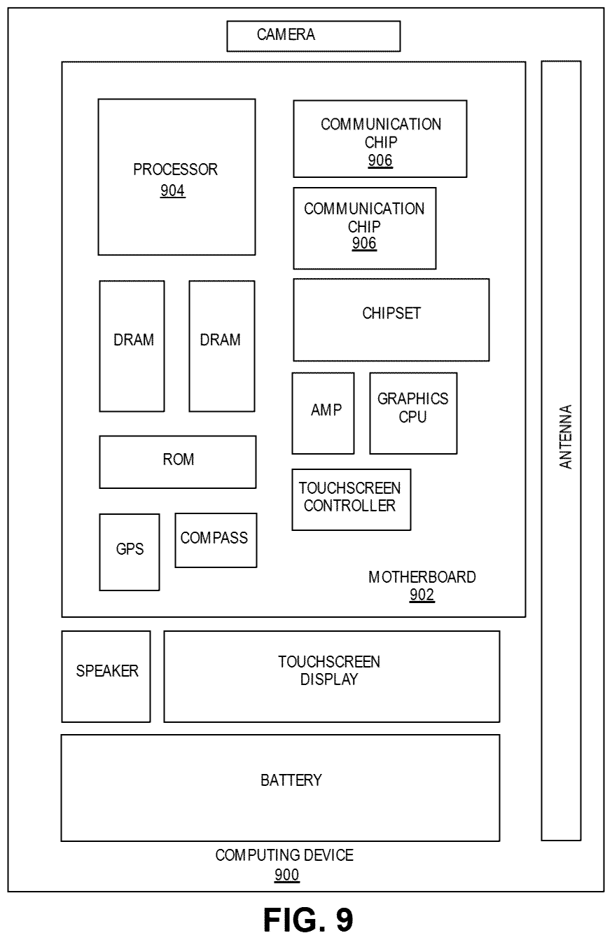

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package with an embedded bridge that includes an integrated inductor, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of an electronic package with an embedded bridge that includes an integrated inductor, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an interconnect bridge, comprising: a substrate; a first trace on the substrate; a first layer on the first trace, wherein the first layer comprises a magnetic material; a second layer over the substrate, wherein the second layer comprises an insulating material; and a second trace embedded in the second layer.

Example 2: the interconnect bridge of Example 1, wherein the substrate comprises silicon or glass.

Example 3: the interconnect bridge of Example 1 or Example 2, wherein the

first trace is a spiral trace.

Example 4: the interconnect bridge of Example 1 or Example 2, wherein the first trace is a serpentine trace.

Example 5: the interconnect bridge of Examples 1-4, wherein the first trace is an inductor trace.

Example 6: the interconnect bridge of Examples 1-5, wherein the first layer is between the second layer and the substrate.

Example 7: the interconnect bridge of Examples 1-5, wherein the substrate is between the first layer and the second layer.

Example 8: the interconnect bridge of Examples 1-7, further comprising: a third trace over the first trace, wherein the first layer is on the third trace.

Example 9: the interconnect bridge of Example 8, wherein a shape of the first trace and a shape of the third trace are chiral images of each other.

Example 10: the interconnect bridge of Examples 1-8, further comprising: a trench inductor into a cavity into the substrate.

Example 11: an electronic package, comprising: a package substrate; a bridge on the package substrate, wherein the bridge comprises: first traces; and a second trace, wherein the second trace is surrounded on at least three sides by a magnetic layer; a first die coupled to the package substrate; and a second die coupled to the package substrate, wherein the first traces communicatively couple the first die to the second die.

Example 12: the electronic package of Example 11, wherein the second trace is below the first traces.

Example 13: the electronic package of Examples 11-12, wherein the second trace comprises a spiral pattern or a serpentine pattern.

Example 14: the electronic package of Examples 11-13, further comprising: a third trace over the second trace.

Example 15: the electronic package of Example 14, wherein the third inductor trace is chiral with respect to the second trace.

Example 16: the electronic package of Examples 11-15, wherein the first die comprises a first voltage regulator and the second die comprises a second voltage regulator, and wherein the first voltage regulator and the second voltage regulator are coupled to the second trace.

Example 17: the electronic package of Example 11, wherein the bridge is embedded in the package substrate.

Example 18: an electronic system, comprising: a board; a package substrate coupled to the board; a bridge on the package substrate, wherein the bridge comprises: an inductor embedded in a magnetic layer; a first die coupled to the package substrate; and a second die coupled to the package substrate, wherein the first die is communicatively coupled to the second die by the bridge.

Example 19: the electronic system of Example 18, wherein the inductor comprises a spiral trace or a serpentine trace.

Example 20: the electronic system of Example 18 or Example 19, wherein the electronic system is part of a personal computer, a server, a mobile device, a tablet, or an automobile.

What is claimed is:

1. An interconnect bridge, comprising:
a substrate;
a first trace on the substrate;
a first layer on the first trace, wherein the first layer comprises a magnetic material;
a second layer over the substrate, wherein the second layer comprises an insulating material; and
a second trace embedded in the second layer.

2. The interconnect bridge of claim 1, wherein the substrate comprises silicon or glass.

3. The interconnect bridge of claim 1, wherein the first trace is a spiral trace.

4. The interconnect bridge of claim 1, wherein the first trace is a serpentine trace.

5. The interconnect bridge of claim 1, wherein the first trace is an inductor trace.

6. The interconnect bridge of claim 1, wherein the first layer is between the second layer and the substrate.

7. The interconnect bridge of claim 1, wherein the substrate is between the first layer and the second layer.

8. The interconnect bridge of claim 1, further comprising:
a third trace over the first trace, wherein the first layer is on the third trace.

9. The interconnect bridge of claim 8, wherein a shape of the first trace and a shape of the third trace are chiral images of each other.

10. The interconnect bridge of claim 1, further comprising:
a trench inductor into a cavity into the substrate.

11. An electronic package, comprising:
a package substrate;
a bridge on the package substrate, wherein the bridge comprises:
first traces; and
a second trace, wherein the second trace is surrounded on at least three sides by a magnetic layer;
a first die coupled to the package substrate; and
a second die coupled to the package substrate, wherein the first traces communicatively couple the first die to the second die.

12. The electronic package of claim 11, wherein the second trace is below the first traces.

13. The electronic package of claim 11, wherein the second trace comprises a spiral pattern or a serpentine pattern.

14. The electronic package of claim 11, further comprising:
a third trace over the second trace.

15. The electronic package of claim 14, wherein the third inductor trace is chiral with respect to the second trace.

16. The electronic package of claim 11, wherein the first die comprises a first voltage regulator and the second die comprises a second voltage regulator, and wherein the first voltage regulator and the second voltage regulator are coupled to the second trace.

17. The electronic package of claim 11, wherein the bridge is embedded in the package substrate.

18. An electronic system, comprising:
a board;
a package substrate coupled to the board;
a bridge on the package substrate, wherein the bridge comprises:
an inductor embedded in a magnetic layer,
a first die coupled to the package substrate; and
a second die coupled to the package substrate, wherein the first die is communicatively coupled to the second die by the bridge.

19. The electronic system of claim 18, wherein the inductor comprises a spiral trace or a serpentine trace.

20. The electronic system of claim 18, wherein the electronic system is part of a personal computer, a server, a mobile device, a tablet, or an automobile.
